(19) United States
(12) Patent Application Publication
(10) Pub. No.: US 2012/0074929 A1
(43) Pub. Date: Mar. 29, 2012

(54) Inductive Current Sensor

(76) Inventor: Darold Wobschall, Williamsville, NY (US)

(21) Appl. No.: 13/246,670

(22) Filed: Sep. 27, 2011

Related U.S. Application Data
(60) Provisional application No. 61/386,685, filed on Sep. 27, 2010.

(51) Int. Cl. G01R 19/00; G01R 1/20

(52) U.S. Cl. 324/126

(57) ABSTRACT

A power meter is disclosed. The power meter may be used to determine the electric power being delivered by a conductor. In one such power meter there is a substrate, an inductive pickup coil attached to the substrate, a conductor, and a detector. The pickup coil may be printed on the substrate.

### CROSS-REFERENCE TO RELATED APPLICATION

This application claims the benefit of priority to U.S. provisional patent application Ser. No. 61/386,685, filed on Sep. 27, 2010.

### FIELD OF THE INVENTION

The present invention relates to electrical sensors for measuring power delivered by a conductor.

### BACKGROUND OF THE INVENTION

There are many methods and devices which can be used to measure the power being delivered by an electrical conductor. In one such device, often referred to as a shunt, a resistor having a known resistance is placed in the conductive path, and the voltage across this resistor is measured. This is a simple, accurate method of determining the power being delivered via the conductor. However, by using the shunt, the conductive path is not isolated from the power measuring equipment. Also, an existing conductor must be cut in order to insert the shunt into the conductor.

Another method uses a current transformer. A primary winding is inserted into the conductive path. A secondary winding provides a proportional but smaller current, which is delivered to a resistor having a known resistance. The voltage across the resistor is measured, and from this measurement the power is determined. An advantage of using a current transformer is that the conductive path is somewhat isolated from the power measuring equipment, and this method is scalable to accommodate measuring low or high currents. However, this method of measuring power is not often desirable because the wire carrying the current (in this case, the conductor) must be broken to install the doughnut-shaped current sensor.

A third method uses a clamp-on probe. Such probes have movable jaws, similar to pliers, which clamp around the conductor. The probe includes a magnetic core, shaped like a doughnut, which concentrates the magnetic flux produced by the current passing through the conductor. A variation of this technology is provided by so-called “split core” probes, which include a magnetic core that is selectively opened for placement around a conductor. The sensing element may be a coil (AC) around the magnetic core or a Hall sensor (AC or DC) in a thin gap. An advantage of such probes is that an existing conductor need not be cut (as is the case when using shunt), and the device is easily installed. Also, such devices are somewhat isolated from the conductor, and the range is easily scaled. However the cost of a clamp-on probe or a split-core probe is high, and such devices are often too bulky for permanent installation.

### SUMMARY OF THE INVENTION

The invention may be embodied as a current sensor, which may be used in a power meter for determining the electric power being delivered by a conductor having one or more leads. In one such current sensor there is a substrate, an inductive pickup coil attached to the substrate, a conductor, and a detector. The pickup coil may be printed on the substrate.

The conductor has a conductive lead attached to the substrate proximate to the pickup coil so as to allow a magnetic field created by a voltage in the lead to induce a measurable voltage in the pickup coil. The detector may be electrically connected to the pickup coil and to the lead, and the detector is capable of evaluating the voltage in the pickup coil.

The substrate may have two primary sides, and the pickup coil may be attached to a first one of the primary sides, while the lead is attached to a second of the primary sides. In this manner, the coil and the lead are on opposite sides of the substrate.

A magnetic body may be provided to facilitate the magnetic field from the lead in reaching the coil. The magnetic body may have a cavity through which the lead extends. In one embodiment of the invention, the magnetic body is “E” shaped. A magnetic strip may be positioned so as to sandwich the coil between the strip and the substrate, and thereby further facilitate the magnetic field through the coil.

A second pickup coil may be included. The second pickup coil may be attached to the substrate and proximately placed near the lead. The magnetic field created by electricity moving through the lead extends through the first coil in a first direction, and through the second coil in a second direction. The two coils may be electrically connected to each other in order to add their respective voltages, and thereby facilitate detection of the voltage in the coils.

A power meter according to the invention may include a clamping terminal that holds the lead in order to fix a position of the lead relative to the coil. The clamping terminal may contact the lead and provide a voltage of the lead to the detector. In addition, the clamping terminal may provide electric power to the detector for operating components of the detector.

### BRIEF DESCRIPTION OF THE DRAWINGS

For a fuller understanding of the nature and objects of the invention, reference should be made to the accompanying drawings and the subsequent description. Briefly, the drawings are:

FIG. 1 is a block diagram of a device according to the invention;

FIG. 2 is a perspective plan view of a device according to the invention;

FIG. 3A is an end view of a device according to the invention;

FIG. 3B is a plan view of the device depicted in FIG. 3A;

FIG. 3C is a side view of the device depicted in FIG. 3A;

FIG. 4A is an end view of a device according to the invention;

FIG. 4B is an end view of a device according to the invention;

FIG. 4C is an end view of a device according to the invention;

FIG. 5 is a block diagram of a device according to the invention;

FIG. 6 is a schematic of an integrator that may be used in the invention;

FIG. 7 is a block diagram of a device according to the invention;

FIG. 8 is graphically depicts activities of certain components that may be included in the invention; and

FIG. 9 is a schematic of a system which may include a power meter that is in keeping with the invention.

### FURTHER DESCRIPTION OF THE INVENTION

The invention is an inductive current sensor, which may be included in a power meter. FIG. 1 is a block diagram of a power meter 10 that is in keeping with the invention. The power meter 10 is intended for use in determining the power being delivered by a conductor 13. In most instances the conductor 13 is comprised of two wire-leads 16, and these leads 16 will usually be electrically insulated from each other. Often, such a conductor 13 is originally supplied such that the insulation is a unitary body that maintains a desired distance between the leads 16. The insulation extending between the leads 16 can be cut or torn, if desired.

The power meter 10 of FIG. 1 includes at least one current pickup 19 and at least one voltage pickup 22. The current pickup 19 and voltage pickup 22 are electrically connected to signal processing electronics 25, which may include a microcontroller 28, for signal processing. An output from the microcontroller 28 may be connected to a transmitter 31 (or transceiver) for communicating information determined by the microcontroller 28.

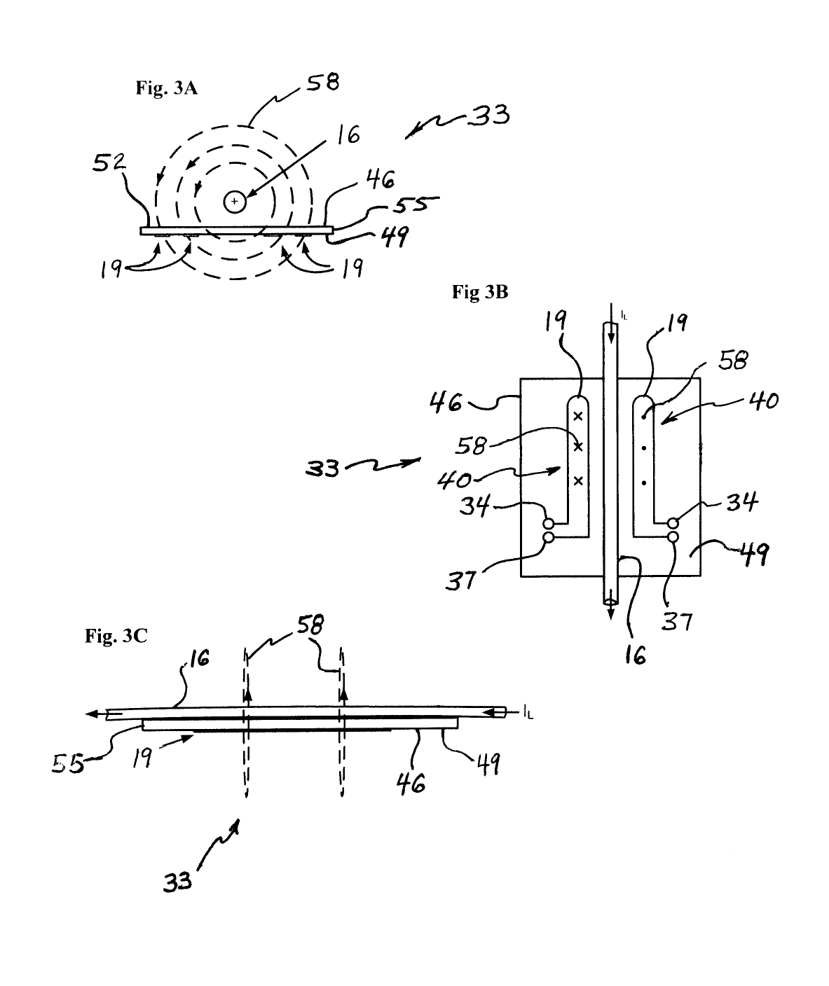

The current pickup 19 is part of an inductive current sensor 33. In one embodiment of the invention, the current sensor 33 has at least one pickup coil 19 associated with each lead 16. Preferably, there are at least two pickup coils 19 associated with each lead 16. Each pickup coil 19 provides a conductive path from a first terminal 34 to a second terminal 37 and the path is arranged to form a nearly enclosed loop 40. Each loop 40 may be arranged near a wire lead 16 of the conductor 13, the power of which is desired to be known. The loops 40 are arranged so that a magnetic field, generated by current passing through the lead 16, passes through the loops 40. FIGS. 3A, 3B and 3C illustrate one arrangement of the loops 40 near a lead 16. FIG. 3A is particularly useful in visualizing the magnetic field that passes through the loops 40 of the pickup coils 19. Note that in this embodiment of the invention, no magnetic core surrounds the lead 16, as might be the case if a clamp-on probe were used. Also, the lead 16 need not be cut, as might be the case if a shunt were used.

With reference to FIGS. 3A, 3B and 3C, the magnetic field passing through the coils 19 causes a voltage to be induced in each of the coils 19. For a single phase load (e.g. motor) the voltages in the two pickup coils 19 are equal in magnitude but opposite in direction, and in this case the right and left pickup coils 19 may be connected (by reversing the leads) so that the voltages of the coils 19 sum together. See FIG. 1. Optionally a center coil 43 (described below) can be added and this would double the voltage, but could make the layout of the current sensor 33 more complicated.

If the conductor 13 is split phase, as is common for residences (220 volts), then the coils 19 measure the currents in the two phases separately. In that case, there are two current channels and two voltage channels which will need to be analyzed by the signal processing electronics 25.

If the coils 19 are electrically connected (e.g. see FIG. 1), the voltage in the coils 19 sums and is delivered to a signal processing electronics 25. The signal processing electronics 25 determines the power delivered by the pickup coils 19 using known methods.

The pickup coils 19 may be mounted on a substrate 46, such as those that are used in printed circuit boards. The pickup coils 19 may be installed on such a substrate by printing or other techniques. Printing the pickup coils 19 on the substrate 46 has the advantage of being inexpensive to manufacture. The substrate 46 may have two primary sides 49, 52 and one or more secondary sides 55, the difference between them being the surface area presented by the sides—primary sides 49, 52 provide a large surface area, and secondary sides 55 have a relatively small surface area. Primary sides 49, 52 are most often large enough to accommodate the mounting of components, while secondary sides 55 usually exist only because there is a thickness to the substrate 46. The pickup coils 19 may be attached to a first of the primary sides 49, while the conductor 13 is positioned adjacent to or on a second of the primary sides 52. In this manner, when oriented in a particular fashion, one might describe the lead 16 as being above the substrate 46 and the pickup coil 16 being below the substrate 46. FIG. 3A shows such an arrangement. It should be noted that FIG. 3A depicts the magnetic field generated by current passing through the lead 16. The magnetic field lines 58 are shown passing through the substrate 46 and through the interior portion of loops 40 of the pickup coils 19. FIGS. 3A and 3B illustrate that the magnetic field lines 58 extend through the right pickup coil 19 in a first direction, and extend through the left pickup coil 19 in a second direction. The magnetic field (B) around the lead 16 at a radius r is proportional to the current in the lead 16:

B(t)=K(r)Iₚ Sin ωt

where ω=2πf and f is the line frequency (e.g. 60 Hz). Although shown for a single sinusoidal wave, it is true also for a current of arbitrary waveform. The proportional constant (K) depends on the distance of the pickup coil 19 from the lead 16.

The pickup voltage (Vp) on the coil 19 (N turns in general) at a particular distance from the power lead 16 is:

Vp=N*A*(dB(t)/dt)

where A is the area of the pickup coil 19 and B is the average magnetic field through the coil 19 produced by the current (I_{L}) in the lead 16.

If the current in the lead 16 is a pure sinusoid (I_{L}*Sin ωt), the induced voltage will be proportional to I_{L}*ω*Cos ωt. Normally, the signal voltage is high enough to be amplified without difficulty especially if the current level is high. Knowing K, N and the amplifier's gain, the amplified signal at the output of the AC/DC section 76 is proportional to the current on the lead 16 (I_{L}) and can be accurately calibrated.

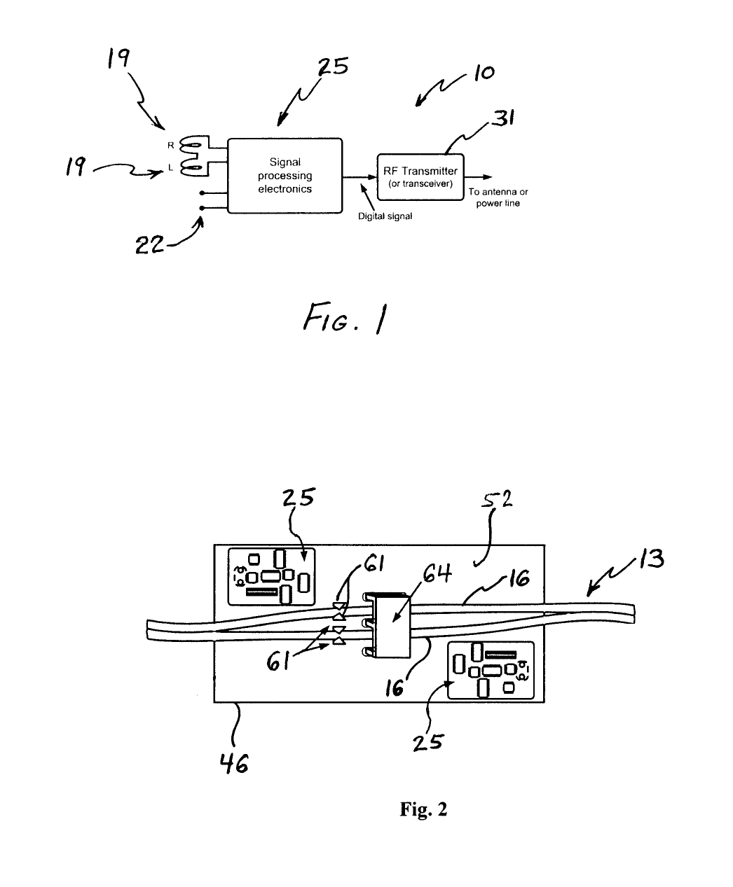

To install the current sensor 33 described above, the leads 16 of the conductor 13 are separated from each other so as to allow each lead 16 to be received by a different set of clamping terminals 61 (see FIG. 2). Each wire lead may be held in the proper position relative to the pickup coils 19 by the clamping terminals 61, which may be mounted to the substrate 46. From a “plan” view (see FIG. 3B) of this arrangement, each wire lead 16 is positioned between the loops 40 of the pickup coils 19, but in fact, the wire lead 16 need not be truly between the loops 40. In this manner, the magnetic field extends through one of the coils 19 in a direction that is different from the direction in which the magnetic field extends through the other of the coils 19. FIGS. 3A and 3B illustrate the differing directions.

In one embodiment of the invention, a magnetic body 64 may be added. Such a magnetic body 64 may facilitate the magnetic field passing through the loops 40 of the pickup coils 19 and/or reduce interference from external influences. The magnetic body 64 may be made of a material similar to that used for a transformer, a clamp-on probe or a split-core current transformer probe.

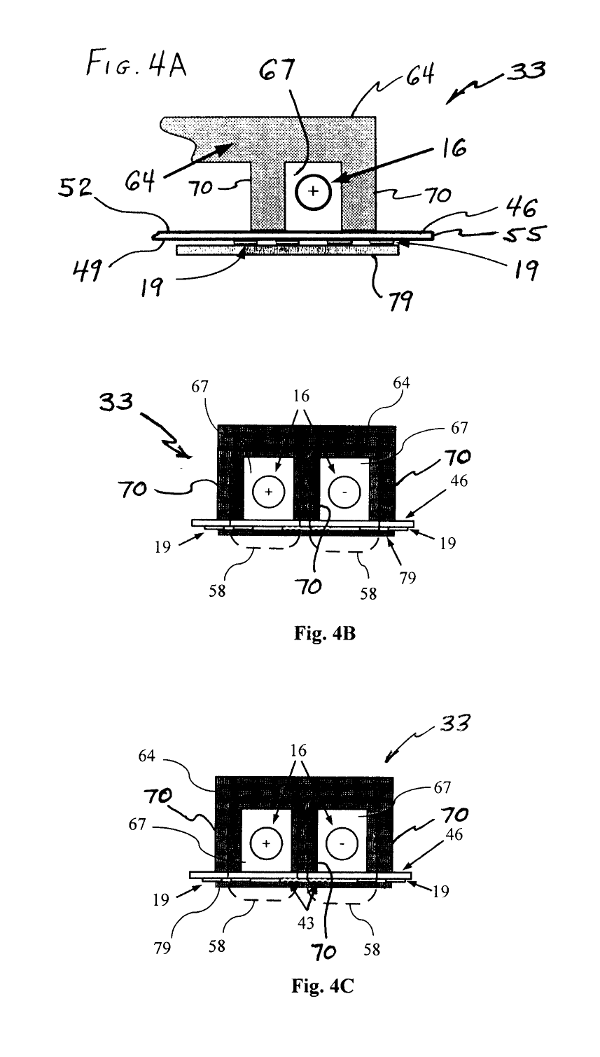

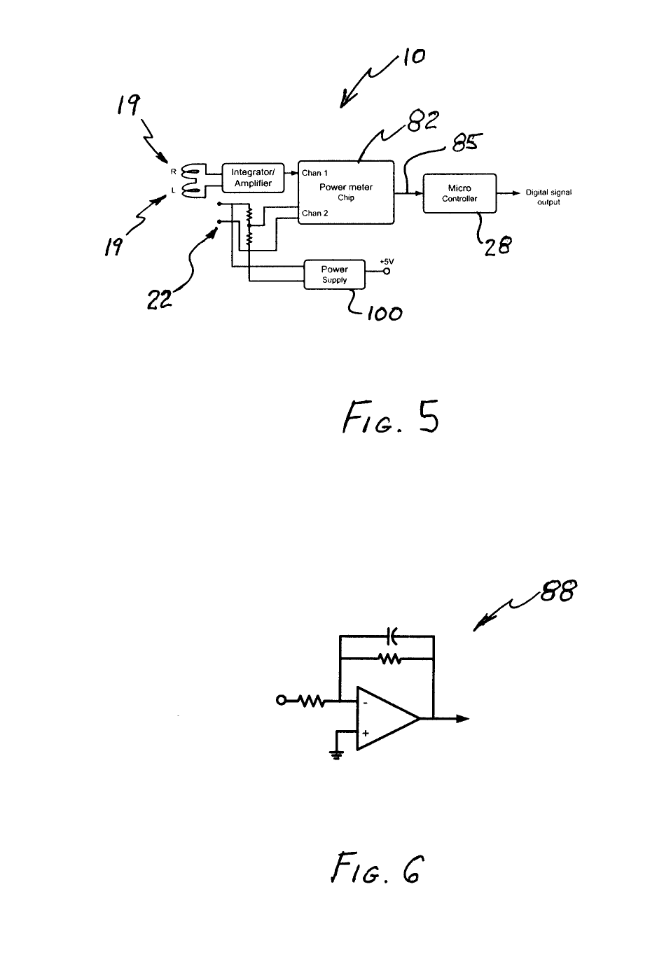

Such a magnetic body 64 may be shaped to provide a cavity 67 through which the leads 16 of the conductor 13 may extend. One such magnetic body 64 has the shape of a capital letter “E”, and this shape provides two cavities 67, with the center leg 70 of the “E” constituting the boundary between the cavities 67. Each leg 70 of the E-shaped magnetic body 64 may be positioned so as to terminate near a loop 40. By placing the E-shaped magnetic body 64 so that the leads 16 of the conductor 13 extend through the cavities 67, magnetic fields generated by the leads 16 are facilitated in reaching the pickup coils 19. FIG. 4A shows such an arrangement. In the arrangement of FIG. 4A, each wire lead 16 of the conductor 13 is associated with two loops 40.

FIG. 4B shows a variation in which there are an equal number of loops 40 and leads 16. In this arrangement, when viewed in the “plan” view, both wire leads 16 of the conductor 13 are positioned between the left and right pickup coils 19. Although magnetic flux from both leads 16 will generate voltage in each loop 40, voltage in the left pickup coil 19 will be driven primarily by the left lead 16, and voltage in the right pickup coil 19 will be driven primarily by the right lead 16. Although FIG. 4B shows this arrangement of pickup coils 19 and leads 16 in conjunction with a magnetic body 64, a current sensor 33 according to the invention can be implemented with this arrangement of coils 19 and leads 16 without the magnetic body 64.

FIG. 4C shows yet another arrangement in which a center pickup coil 43 is positioned, from the “plan” view perspective, between the leads 16 of the conductor 13. Although FIG. 4C shows this arrangement of pickup coils 19 and leads in conjunction with a magnetic body 64, a current sensor 33 according to the invention can be implemented with this arrangement of coils 19 and leads 16 without the magnetic body 64.

FIGS. 4A, 4B and 4C also show an embodiments of the invention in which a magnetic strip 79 is positioned on a side of the substrate 46 that is different from the side of the substrate 46 on which the E-shaped magnetic body 64 resides. By placing the magnetic strip 79 so as to sandwich the pickup coils 19 between the magnetic strip 79 and the substrate 46, the magnetic field is further facilitated, which results in a greater current being induced in the pickup coils 19.

Each clamping terminal 61 may serve as a means to determine the voltage of the lead 16 they are holding. For example, a portion of the clamping terminal 61 may extend through the insulation surrounding the lead 16 to make electrical contact directly with the lead 16. The voltage of each lead 16 may be provided to the signal processor 25 via the clamping terminals 61, and used in determining the power being delivered by the leads 16. In addition, electricity from the leads 16 may be drawn off for purposes of providing power to the components of the signal processor 25. In that case, the clamping terminal 61 may be light-weight when the current draw is small (e.g. under 20 mA).

Until now, the signal processing electronics 25 have been referred to in general terms. Additional detail of one type of signal processing electronics 25 is shown in FIG. 5. In FIG. 5 there is shown a power meter chip 82 having two input channels. On channel #1, the chip 82 receives an alternating-current signal voltage that is proportional to the current from the pickup coils 19. An alternating-current signal that is proportional to the voltage from the output of the voltage divider is presented on channel #2 of the power meter chip 82. The power meter chip 82 may be, for example, a Crystal CS5463 or Analog Devices ADE7854. These chips have internal analog-to-digital converters and digital multipliers that compute true power, accurate RMS current and voltage, as well as other parameters.

Output from the power meter chip 82 may be provided to the micro-controller 28, which may be tasked with reformatting digital data provided at the output of the power meter chip 82 for transmission, for example by radio frequency (“RF”). The micro-controller 28 may provide calibrations, identifications and other features expected of a smart sensor.

Because the voltage induced in the pickup coil 19 (voltage across locations 34 and 37) is proportional to the derivative of the magnetic field and thus the current, it is necessary, at least in the case of non-sinusoid current, to integrate the signal from the pickup coil 19 in order to provide a corrected signal (voltage), which is proportional to the current. This may be done with an integrator/amplifier circuit 88. One such circuit is depicted in FIG. 6.

Electronics for Low-Cost Version: The signal processing electronics 25 described above may be relatively costly. Therefore, a low-cost version of the signal processing electronics 25 may be desirable. FIG. 7 depicts an example of a low-cost signal processor 91 which includes a simplified lower-precision method of converting the AC signal to DC and digitizing. Such a signal processor 91 may measure RMS current and voltage with only modest accuracy (2% to 5%) and may not be provided with circuitry for measuring true power or power factor. To further reduce cost, such a low-cost signal processor may be paired with a low-cost RF transmitter 31.

In the signal processor 91 depicted in FIG. 7, after amplification of the AC signal from the current pickup coils 19 (left and right pickup voltages summed) are converted to DC with a precision AC/DC converter. The output is converted to digital by an analog-to-digital converter 94 (e.g. 10-bit) (“A/D#1”) built into the microcontroller 28. The output of the microcontroller 28 may be scaled so that the nominal full-scale of the current sensor (e.g. 10 amps RMS) is about half-scale on the A/D#1, thus allowing an over-range situation to exist without loss of data. The AC/DC converter 97 or precision rectifier, provides a signal proportional to the AC signal sinewave average but, although calibrated in RMS, does not provide true RMS measurements.

Measurement of the voltage on the leads 16 may be accomplished by monitoring the current drawn by the power supply 100 which increases in proportion to the conductor 13 voltage (with proper design of the power supply 100). This approach relies on the normal rectification of the power supply 100, thus eliminating the need for a separate rectifier to convert the conductor 13 voltage signal to DC.

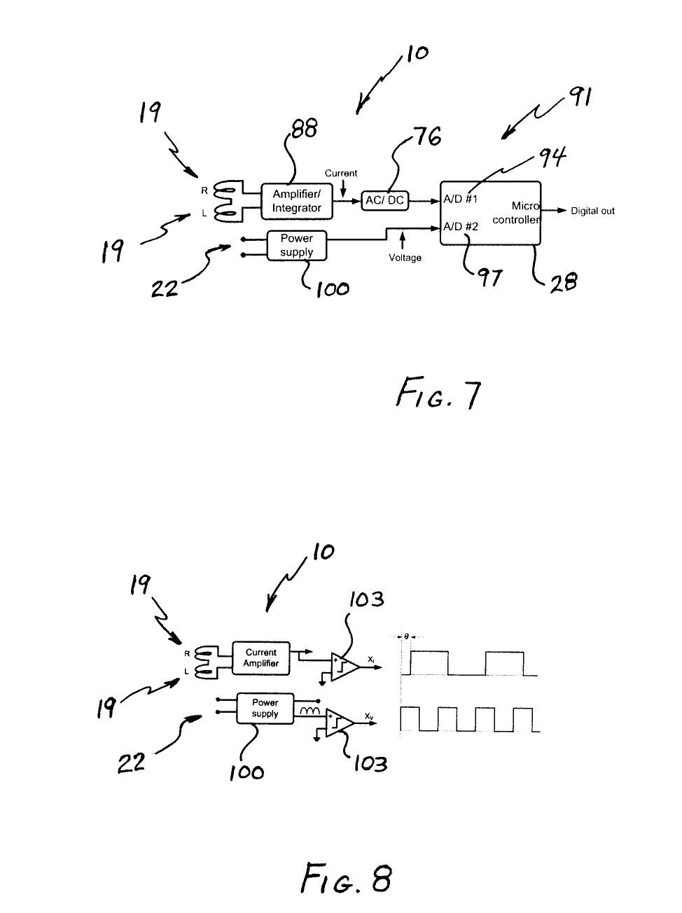

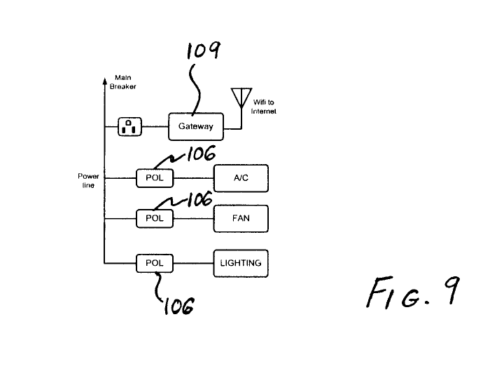

The accuracy of the low-cost signal processor 91 can be improved by measuring the phase difference between the current and the voltage (the more precise version of the signal processor described above does this). To implement this option, zero-crossing comparators 103 may be added to the current and voltage inputs and the resulting square waves sent to the microcontroller 28 for analysis. Differences in the time of the rising edge is proportional to the phase difference (θ)—see FIG. 8. From this, the power factor (Cos θ) may be calculated and applied in order to correct the apparent power (IᵣₘₛVᵣₘₛ) and thereby approximate true power (which may be equal to the true power if there is no harmonic distortion). FIG. 8 graphically depicts these activities.

In the case of the low-cost version of the signal processor 91, the combination of the simplified signal conditioners, small microcontroller 28 and transmit-only RF units depicted in FIG. 7 results in a small number of components, which reduces production costs. Although the precision is not high, for many point-of-load (POL) applications high precision is not needed, but low cost is.

Depicted in FIG. 1, and elsewhere, is an RF transmitter 31. The RF transmitter 31 (or transceiver) of the power meter provides a method of data transmission. In a low-cost version of an RF transmitter 31, an off-the-shelf transmitter (e.g. 433 MHz or 925 MHz) may be used. The RF signal may be radiated from an antenna or coupled to the conductor 13 which serves as an antenna. The RF transmitter 31 may transmit in bursts (e.g., terse SNAP protocol) periodically as a way to conserve power. The RF transmitter 31 may transmit identification and status codes.

In a more precise version of the RF transmitter 31, a higher performance mesh network (Zigbee/6LoWPAN) or WiFi may be utilized. FIG. 9 depicts one such system in which data from several low-cost POL meters 106 may be collected by a receiver on the gateway 109, which may be located on the conductor 13, and the data may be retransmitted via WiFi to the Internet. The RF signal may be coupled to the conductor 13 in order to use the conductor 13 as an antenna, and the RF signal may be picked up by the gateway 109 at some distance from the location where the conductor 13 power is determined.

It will now be recognized that the invention may be embodied as a current sensor using inductive pickup coils 19, which may be mounted to a substrate 46 such as a printed circuit board. A conductor 13, the power of which is to be determined, may be attached to the substrate 46 in a manner that positions the leads 16 of the conductor 13 proximate to the pickup coils 19. The coils 19 may be traces placed directly on the substrate 46, and thereby provide a low-cost way of determining the power being delivered by the conductor 13. Although the signal level provided by the pickup coils 19 may be low, high-gain amplifiers may be used to bring the signal up to a level that can be detected and analyzed by the signal processing electronics 25.

The invention may be implemented in a compact fashion to make it easy to install in locations where space is limited. Furthermore, the dimensions of the substrate may be modified so that it can be easily attached to an existing configuration of conductor 13.

Although the present invention has been described with respect to one or more particular embodiments, it will be understood that other embodiments of the present invention may be made without departing from the spirit and scope of the present invention. Hence, the present invention is deemed limited only by the appended claims and the reasonable interpretation thereof.

What is claimed is:

1. A current sensor, comprising:
a substrate;
an inductive pickup coil attached to the substrate;
a conductor having a conductive lead attached to the substrate proximate to the pickup coil so as to allow a magnetic field created by current in the lead to induce a measurable current in the pickup coil;
a detector electrically connected to the pickup coil and to the lead, the detector being capable of evaluating the current in the pickup coil and the voltage in the lead.

2. The current sensor of claim 1, wherein the pickup coil is printed on the substrate.

3. The current sensor of claim 1, wherein the substrate has two primary sides, and the pickup coil is attached to a first one of the primary sides, and the lead is attached to a second of the primary sides.

4. The current sensor of claim 1, further comprising a magnetic body having a cavity through which the lead extends, the magnetic body facilitating delivery of magnetic flux to the pickup coil.

5. The current sensor of claim 4, further comprising a magnetic strip positioned to sandwich the coil between the strip and the substrate.

6. The current sensor of claim 1, further comprising a second pickup coil attached to the substrate and proximately placed near the lead, wherein a magnetic field created by electricity moving through the lead extends through the first coil in a first direction, and through the second coil in a second direction.

7. The current sensor of claim 1, further comprising a clamping terminal holding the lead so as to fix a position of the lead relative to the coil.

8. The current sensor of claim 7, wherein the clamping terminal contacts the lead and provides electric power to the detector for operating components of the detector.

9. A power meter, comprising:
a substrate;
an inductive pickup coil attached to the substrate;
a conductor having a conductive lead attached to the substrate proximate to the pickup coil so as to allow a magnetic field created by current in the lead to induce a measurable current in the pickup coil;
a detector electrically connected to the pickup coil and to the lead, the detector being capable of evaluating the current in the pickup coil and the voltage in the lead.

10. The power meter of claim 9, wherein the pickup coil is printed on the substrate.

11. The power meter of claim 9, wherein the substrate has two primary sides, and the pickup coil is attached to a first one of the primary sides, and the lead is attached to a second of the primary sides.

12. The power meter of claim 9, further comprising a magnetic body having a cavity through which the lead extends, the magnetic body facilitating delivery of magnetic flux to the pickup coil.

13. The power meter of claim 12, further comprising a magnetic strip positioned to sandwich the coil between the strip and the substrate.

14. The power meter of claim 9, further comprising a second pickup coil attached to the substrate and proximately placed near the lead, wherein a magnetic field created by electricity moving through the lead extends through the first coil in a first direction, and through the second coil in a second direction.

15. The power meter of claim 9, further comprising a clamping terminal holding the lead so as to fix a position of the lead relative to the coil.

16. The power meter of claim 15, wherein the clamping terminal contacts the lead and provides a voltage of the lead to the detector.

17. The power meter of claim 16, wherein the clamping terminal provides electric power to the detector for operating components of the detector.
